(19) United States
(12) Patent Application Publication
(10) Pub. No.: US 2022/0389611 A1
(43) Pub. Date: Dec. 8, 2022

(54) METHOD FOR PRODUCING CHEMICAL VAPOUR DEPOSITION DIAMOND

(71) Applicant: ELEMENT SIX TECHNOLOGIES LIMITED, DIDCOT, OXFORDSHIRE (GB)

(72) Inventors: GRUFFUDD TREFOR WILLIAMS, DIDCOT (GB); CHRISTOPHER JOHN HOWARD WORT, DIDCOT (GB)

(73) Assignee: ELEMENT SIX TECHNOLOGIES LIMITED, DIDCOT, OXFORDSHIRE (GB)

(21) Appl. No.: 17/770,918

(22) PCT Filed: Dec. 15, 2020
(86) PCT No.: PCT/EP2020/086311

§ 371 Date: Apr. 21, 2022

(30) Foreign Application Priority Data
Dec. 19, 2019 (GB) 1918883.8

(51) Int. Cl. C30B 29/04; C30B 25/20; C23C 16/27

(52) U.S. Cl. CPC C30B 29/04; C30B 25/20; C23C 16/27

(57) ABSTRACT

A method of fabricating a CVD synthetic diamond material, the method comprising providing a compacted diamond carrier material consisting of compacted non-intergrown diamond particles substantially free of a second phase, and growing CVD synthetic diamond material on a surface of the compacted diamond carrier material. Composite diamond bodies made by the method are also described.

### FIELD

The present invention relates to the field of producing chemical vapour deposition (CVD) diamond.

### BACKGROUND

CVD processes for synthesis of diamond material are well known in the art. Being in the region where diamond is metastable compared to graphite, synthesis of diamond under CVD conditions is driven by surface kinetics and not bulk thermodynamics. Diamond synthesis by CVD is normally performed using a small fraction of carbon (typically <5%), typically in the form of methane although other carbon containing gases may be utilized, in an excess of molecular hydrogen. If molecular hydrogen is heated to temperatures in excess of 2000 K, there is a significant dissociation to atomic hydrogen. Various methods are available for heating carbon containing gas species and molecular hydrogen in order to generate the reactive carbon containing radicals and atomic hydrogen for CVD synthetic diamond growth including arc-jet, hot filament, DC arc, oxy-acetylene flame, and microwave plasma.

In the presence of a suitable substrate material, CVD synthetic diamond material can be deposited. Polycrystalline CVD diamond material may be formed on a non-diamond substrate, typically formed of a carbide forming material such as silicon, silicon carbide, or refractory metals such as molybdenum, tungsten, titanium, etc. Single crystal CVD synthetic diamond material may be formed by growth on a single crystal diamond substrate. There are several advantages to single crystal CVD diamond material for certain applications due to the avoidance of grain boundaries, e.g. higher thermal conductivity for thermal heat spreading applications and lower scattering of light for certain optical applications. However, to date single crystal CVD diamond material is only available in relatively small sizes and thus for many applications polycrystalline CVD diamond components are still preferred, e.g. for large area optical windows and heat spreaders.

It has been proposed to combine the more extreme characteristics of single crystal CVD diamond material with large area polycrystalline CVD diamond wafers by providing composite wafers comprising a plurality of single crystal diamond substrates bonded to a polycrystalline CVD diamond carrier wafer. Such composite substrates are described in WO 2005/010245 and comprise a polycrystalline CVD diamond support layer and a plurality of single crystal diamond substrates fixed to the polycrystalline CVD diamond support layer. Device structures can then be fabricated on the plurality of single crystal diamond substrates. Various ways of bonding the single crystal diamond substrates to the polycrystalline CVD diamond support layer are described in WO 2005/010245 including the use of adhesives such as gluing or brazing. WO 2005/010245 also indicates that a preferred bonding method is direct diamond-to-diamond bonding by growing the polycrystalline CVD diamond support layer directly onto an array of single crystal diamond substrates. For example, WO 2005/010245 suggests that single crystal diamond substrates can be attached to a backing wafer such as silicon, tungsten or polycrystalline diamond and a layer of polycrystalline CVD diamond grown thereon. Subsequently the backing wafer can be retained or removed, for example, to provide a polycrystalline CVD diamond wafer in which a plurality of single crystal diamond substrates are disposed with both surfaces of the single crystal diamond substrates exposed, e.g. to provide optical windows.

Having regard to single crystal CVD diamond growth, it is commercially advantageous to synthesize a plurality of single crystal CVD diamonds in a single growth run. A plurality of single crystal CVD synthetic diamonds can be fabricated in a single CVD growth run by providing a plurality of single crystal diamond substrates on a carrier substrate. The carrier substrate is typically formed of a carbide forming material such as silicon, silicon carbide, or refractory metals such as molybdenum, tungsten, titanium, etc. The substrates can be placed on a refractory metal carrier substrate or bonded thereto using methods known in the art. One problem with this approach to synthesizing a plurality of single crystal CVD diamonds is that of uniformity and yield. Non-uniformities can exist in terms of crystal morphology, growth rate, cracking, and impurity content and distribution. Even if the CVD diamond growth chemistry is carefully controlled, non-uniform uptake of impurities can still occur due to temperature variations at the growth surface which affect the rate of impurity uptake. Variations in temperature also cause variations in crystal morphology, growth rate, and cracking issues. These temperature variations can be in a lateral direction relative to the growth direction at a particular point in the growth run (spatially distributed) or parallel to the growth direction due to variations in temperature over the duration of a growth run (temporally distributed). Variations can occur within a single CVD diamond stone and also from stone to stone in a multi-stone synthesis process. As such, in a multi-stone synthesis process only a portion of product diamond stones from a single growth run may meet a target specification. A good thermal contact between the carrier substrate and the substrate can ameliorate some of these issues.

In addition to the above, contamination of the single crystal CVD diamond product stones can result as material from the carrier substrate is etched away and becomes incorporated into the single crystal CVD diamond material during growth. In this regard, it may be noted that impurities in the CVD processes are critical to the type of diamond material which is produced. For example, various impurities may be intentionally introduced into the CVD process gases, or intentionally excluded from the CVD process gases, in order to engineer a CVD synthetic diamond material for a particular application. Furthermore, the nature of the substrate material and the growth conditions can affect the type and distribution of defects incorporated into the CVD synthetic diamond material during growth.

A further issue is unwanted delamination of the diamond from the carrier substrate in the event that the growth process is interrupted. The growth process can take many weeks depending on the thickness of diamond required. If the power supply is interrupted in that time, the diamond and the carrier substrate cool down. The mismatch in the thermal expansion coefficient between the diamond and the carrier substrate can cause the diamond to delaminate from the carrier substrate. The process cannot simply be restarted because the delamination affects the thermal contact between the carrier substrate and the diamond, and so a low yield results.

### SUMMARY

Effective thermal management is a key feature for achieving uniform CVD diamond material at high yields according to a target specification. This applies to both single crystal and polycrystalline CVD diamond material. It is an aim of embodiments of the present invention to address these issues and provide an improved growth process and carrier substrate.

According to a first aspect, there is provided a method of fabricating a CVD synthetic diamond material. The method comprises providing a compacted diamond carrier material consisting of compacted non-intergrown diamond particles substantially free of a second phase, and growing CVD synthetic diamond material on a surface of the polycrystalline diamond carrier material. An advantage of this is that the compacted diamond carrier material and the grown CVD diamond have comparable thermal expansion coefficients, which means that there is a greatly reduced risk of delamination between the carrier and the growing CVD synthetic diamond material.

This allows growth to be restarted if required. If desired, a processing step can be applied between restarts.

As an option, the method further comprises separating the grown CVD synthetic diamond material from the compacted diamond carrier material.

As an option, the compacted diamond carrier material has a density of between 80.0 and 99.5% of the theoretical density of diamond.

As an option, the compacted diamond carrier material has a largest dimension in a range 30 mm to 200 mm. For example, if the carrier material is circular in plan view, the largest dimension is the diameter.

The compacted diamond carrier material optionally has a thickness in a range 3 mm to 20 mm.

As an option, the compacted diamond carrier material has an Rₐ surface roughness in a range of 0.05 μm to 3 μm.

As an option, the compacted diamond carrier material has a non-planar surface profile.

The grown CVD synthetic diamond material is optionally polycrystalline CVD synthetic diamond material.

As an option, the method further comprises attaching at least one single crystal diamond seed to the compacted diamond carrier material. In this case, the grown CVD synthetic diamond material comprises a single crystal CVD diamond grown on the single crystal diamond seed, and the method further comprising separating the grown single crystal CVD diamond from the compacted diamond carrier material and any polycrystalline CVD diamond material which has grown to yield a grown single crystal CVD diamond.

As a further option, the single crystal diamond seed is attached to the compacted diamond carrier material by a method selected from any of soldering to a surface of the compacted diamond carrier material, brazing to a surface of the compacted diamond carrier material, embedding the single crystal diamond seed into the surface of the compacted diamond carrier material and/or locating the single crystal diamond seed in a recess in the surface of compacted diamond carrier material.

As a further option, bonding between the single crystal diamond seed and the compacted diamond carrier material is achieved by heating in a reducing atmosphere. Optionally, the heating is achieved by induction heating. As an option, growth of the single crystal CVD diamond on the single crystal diamond seed is controlled such that a ratio of the single crystal CVD diamond growth rate to the polycrystalline CVD diamond growth rate is >0.5, >0.75, >1.0, >1.5, >1.75, or >2. The grown single crystal CVD diamond optionally has a variation in a growth parameter selected from any of less than 1, less than 0.5, less than 0.3, less than 0.2, and less than 0.1.

The method optionally comprises growing the single crystal CVD diamond at a temperature under 1000° C.

As a further option, the method comprises, after growing CVD synthetic diamond material on the compacted diamond carrier material, stopping the growth process and subsequently growing further CVD synthetic diamond material on the grown CVD synthetic diamond material.

Optionally, the method comprises providing the compacted diamond carrier material by compacting diamond grit at a temperature between 750° C. and 2000° C. and a pressure of between 3 and 8 GPa.

As an option, the diamond grit is high temperature high pressure, HPHT, diamond grit.

The method optionally comprises machining the compacted diamond carrier material.

As an option, the method further comprises dry seeding a surface of the compacted diamond carrier material with diamond powder.

As an option, the compacted non-intergrown diamond particles forming the compacted diamond carrier material are bonded to adjacent diamond particles via a layer of non-diamond carbon.

The compacted diamond carrier material is optionally part of a composite structure, the composite structure further comprising a substrate of synthetic diamond material to which the compacted diamond carrier material is attached, the substrate of synthetic diamond material having a higher thermal conductivity than the compacted diamond carrier material.

According to second aspect, there is provided a composite diamond body comprising a layer of compacted diamond carrier material consisting of compacted non-intergrown diamond particles substantially free of a second phase, and at least one single crystal diamond material wafer affixed to a surface of the layer of compacted non-intergrown diamond particles.

According to third aspect, there is provided a composite diamond body comprising a layer of compacted diamond carrier material consisting of compacted non-intergrown diamond particles substantially free of a second phase, and a layer of CVD synthetic polycrystalline diamond material grown on a surface of the first layer. As an option, the CVD synthetic polycrystalline diamond material has a thickness in a range of 1 to 10 mm.

As an option for the second and third aspects, the composite diamond body comprises a first layer of compacted diamond carrier material consisting of compacted non-intergrown diamond particles substantially free of a second phase, and a second layer of synthetic diamond material to which the first layer is attached, the second layer having a higher thermal conductivity than the first layer.

As an option for the second and third aspects, the compacted diamond carrier material has a largest dimension in a range 30 mm to 200 mm.

As an option for the second and third aspects, the compacted diamond carrier material has a thickness in a range 3 mm to 20 mm.

As an option for the second and third aspects, the compacted diamond carrier material has an Rₐ surface roughness in a range of 0.05 μm to 3 μm.

The compacted diamond carrier material described in the second and third aspects optionally comprises discrete pieces of compacted diamond carrier material joined together.

### BRIEF DESCRIPTION OF DRAWINGS

Non-limiting embodiments will now be described by way of example and with reference to the accompanying drawings in which:

FIG. 1 is a flow diagram showing exemplary steps for growing polycrystalline CVD diamond;

FIG. 2 is a flow diagram showing exemplary steps for growing single crystal CVD diamond;

FIG. 3 illustrates schematically a side elevation cross section view of a compacted diamond carrier substrate with diamond seeds brazed to its surface;

FIG. 4 illustrates schematically a side elevation cross section view of a compacted diamond carrier substrate with diamond seeds embedded into its surface;

FIG. 5 illustrates schematically inter-grown diamond grains formed by HPHT sintering of diamond in the presence of a catalyst;

FIG. 6 illustrates schematically compacted diamond grains formed by HPHT sintering of diamond without any catalyst or sintering aid;

FIG. 7 is a graph showing rate of removal of hot compacted diamond carrier material during a lapping operation;

FIG. 8 is a graph showing rate of removal of polycrystalline diamond material during a lapping operation;

FIG. 9 illustrates schematically in plan view a hot compacted diamond carrier formed from multiple sections of hot compacted diamond carrier; and

FIG. 10 is a photograph showing a side elevation view of sectioned CVD polycrystalline diamond grown on a hot compacted diamond carrier;

FIG. 11 is a photograph showing a side elevation view of sectioned CVD single crystal diamond grown on a hot compacted diamond carrier; and

FIG. 12 illustrates schematically a further embodiment of a side elevation cross section view of a further embodiment of a compacted diamond carrier substrate.

### DETAILED DESCRIPTION

WO 02/09909 describes a process in which plastically deformed grits of high-pressure high-temperature (HPHT) diamond are compacted together without any bonding or sintering aid such as a solvent or catalyst. This forms a polycrystalline diamond compact of self-bonded diamond particles that is substantially free of a second phase or additional components. Compaction is performed at temperatures between 750 and 2000° C. and in a pressure range of 3 to 8 GPa. The pressure and temperature are selected so as to be in the region of diamond thermodynamic stability in the graphite-diamond phase diagram.

It is proposed in WO 02/09909 that plastic deformation of the particles prior to compaction is thought to improve the strength of the resultant polycrystalline diamond compact. Plastic deformation is introduced by crushing diamond grits to produce diamond particles of irregular shape, which have sharp points and edges in addition to flat areas. During compaction, very high contact pressures are thought to be generated when a point or edge bears upon a substantially flat surface of an adjacent diamond particle. Such high contact pressure when applied at elevated temperature causes plastic deformation at the contact points between particles thereby facilitating self-bonding. The extent of the self-bonding determined the strength and friability of the polycrystalline diamond compact. However, as explained below, the present inventors are of the view that binding between non-diamond carbon at the surface of diamond grains is more important to form a rigid compacted structure.

The inventors have realised that a polycrystalline diamond compact such as that described above containing no second phase (other than unavoidable impurities, or diamond that contains one or more dopants such as boron, nitrogen or silicon) can be used as a substrate for CVD synthesis of diamond. Polycrystalline diamond compacts prepared in this way have an adequate handling strength, can be polished to give a required surface finish and can be easily machined away from the grown diamond. The main advantage of using a compacted polycrystalline diamond compact as a carrier substrate is that it has the same thermal expansion coefficient as the diamond grown on it, and so the likelihood of delamination of the grown diamond from the carrier substrate is greatly reduced.

It has been found that single phase polycrystalline diamond material compacts have a density of at least 80% of the theoretical density of diamond, even when sintered at the relatively low temperature of 800° C. at a pressure of 5.5. GPa.

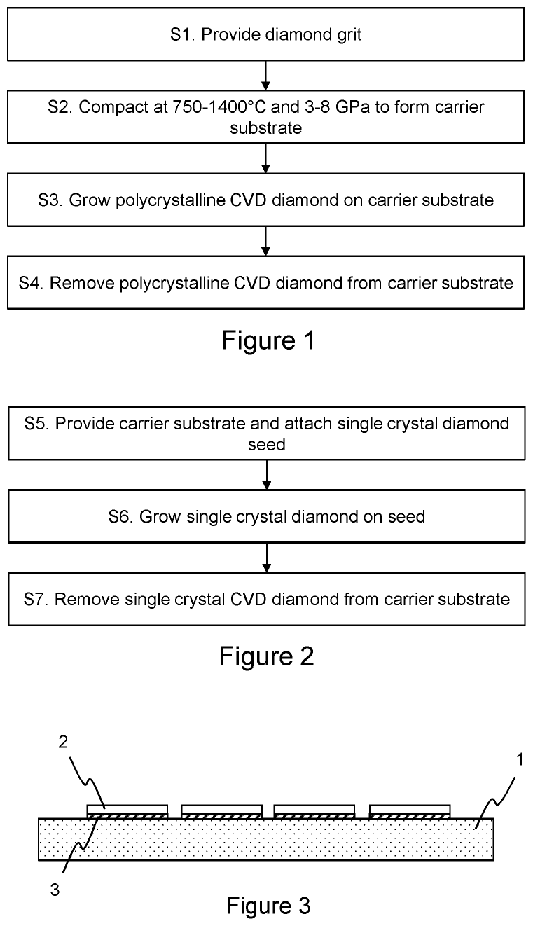

FIG. 1 herein is a flow diagram showing exemplary steps for growing polycrystalline CVD diamond. The following numbering corresponds to that of FIG. 1:

S1. Diamond grit is provided. This may be sourced from natural diamond, HPHT diamond, or CVD diamond. The grit may be plastically deformed, as described in WO 02/09909, but this is not critical.

S2. The diamond grit is compacted at a temperature between 750° C. and 2000° C. and in a pressure range of 3 GPa to 8 GPa, with no other phase such as a sintering aid being present. The resultant compact is to be used as a compacted diamond carrier. The compacted diamond carrier material may be further processed, for example by lapping to form a flat surface, machining to form a profiled surface, polishing to reduce surface roughness, and dusting with diamond seeds to aid nucleation and synthesis. Note that a non-planar profiled surface could also be formed. 3. The method according to claim 1 or claim 2, wherein the compacted diamond carrier material has a density of between 80.0 and 99.5% of the theoretical density of diamond. Exemplary largest dimensions for the compacted diamond carrier material are in a range 30 mm to 200 mm. Where the compacted diamond carrier material is circular in plan view, the largest dimension is a diameter. The compacted diamond carrier material has an exemplary thickness in a range 3 mm to 20 mm. A key issue affecting the required thickness are the fracture strength and hence how easy the material is to handle. The compacted diamond carrier material has an Rₐ surface roughness in a range of 0.05 μm to 3 μm. It may be polished to a required surface roughness, or it may be unpolished.

S3. The compacted diamond carrier material is placed in a CVD reactor and polycrystalline CVD synthetic diamond material is grown on the on the compacted diamond carrier material.

S4. If required, the resultant polycrystalline CVD synthetic diamond material is separated from the compacted diamond carrier material.

FIG. 2 herein is a flow diagram showing exemplary steps for growing single crystal CVD diamond. The following numbering corresponds to that of FIG. 2:

S5. A compacted diamond carrier is formed in the same way as described above in steps S1 and S2. At least one single crystal diamond seed is attached to the compacted diamond carrier material. Attachment may be effected by brazing the seed to the surface, soldering the seed to the surface, diffusion bonding the seed to the surface, embedding the seed in the surface, locating the seed in a recess in the surface or heating the seed and the carrier substrate in a reducing atmosphere to bond the seed to the surface.

Turning now to FIG. 3, there is illustrated schematically a side elevation cross section view of a compacted diamond carrier material 1 having four diamond seeds 2 attached to it by way of a braze material 3. A strong carbide-forming braze ensures gives good mechanical and thermal integrity when thermally cycled.

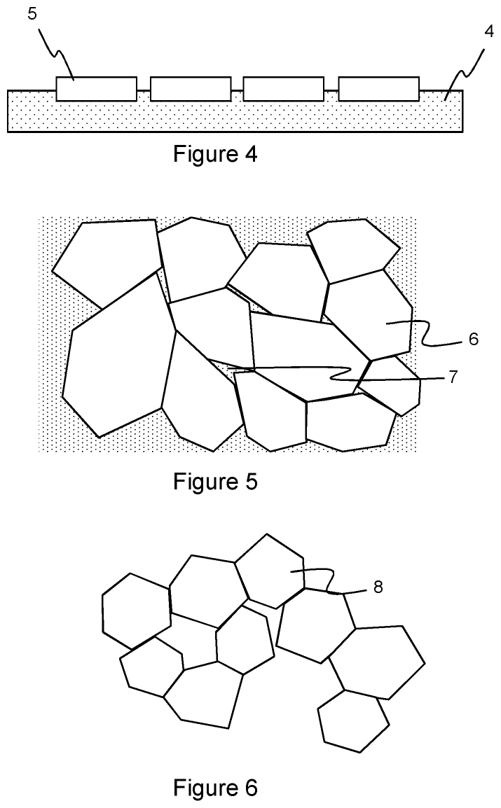

Turning now to FIG. 4, there is illustrated schematically a side elevation cross section view of a compacted diamond carrier material 4 having four single crystal diamond seeds 5 embedded into its surface. The seeds can be directly pressed to embed them, which ensures that the seeds are mechanically and thermally sunk and will not move.

A similar effect can be achieved by processing recesses into the compacted diamond carrier material 4 and locating the seeds in the recesses.

S6. The compacted diamond carrier material is placed in a CVD reactor and single crystal CVD synthetic diamond material is grown on the on the single crystal diamond seed. Growth of the single crystal CVD diamonds on the single crystal diamond seed may be controlled such that a ratio of the single crystal CVD diamond growth rate to the polycrystalline CVD diamond growth rate is >0.5, >0.75, >1.0, >1.5, >1.75, or >2. The grown single crystal CVD diamond has a variation in a growth parameter selected from any of less than 1, less than 0.5, less than 0.3, less than 0.2, and less than 0.1. The skilled person would appreciate that growth at a temperature below 1000° C. favours growth of single crystal rather than polycrystalline diamond.

S7. The grown single crystal CVD diamond is separated from the compacted diamond carrier material and any polycrystalline CVD diamond material which has grown, to yield a grown single crystal CVD diamond.

Note that for the processes described in FIGS. 1 and 2, it is possible to stop the growth process and restart it. The match in the thermal expansion coefficients between the growing diamond and the compacted diamond carrier material means that delamination is unlikely and a good thermal contact is maintained between the growing diamond and the carrier substrate.

The ability to stop and start the growth process, even after cooling to room temperature, is very useful to make a production process more robust. However, it brings other advantages. For example, when the grown diamond is polycrystalline CVD diamond it allows different layers to be grown. In one example, a first layer of polycrystalline CVD diamond suitable for use as a heat spreader is grown. This can be removed from the reactor, polished, re-seeded with diamond particles and then a further layer of polycrystalline CVD diamond suitable for use in an optical application may be grown over the first layer. Furthermore, layers may be etched and/or masked between growth steps to introduce features into the polycrystalline CVD diamond.

A similar approach may be used with single crystal diamond material. Masking and etching can be used to put in trenches or other surface structures, and over-grow layers with different dopants or properties. This allows the growth of single crystal CVD diamonds with sub-surface features without having to remove the partially grown single crystal CVD diamond from the compacted diamond carrier material and re-attach it before different growth steps. Furthermore, the mechanical robustness of the compacted diamond carrier material allows small single crystal samples to be more easily handled during processing, and allows CVD single crystal CVD diamonds to be processed at the same time while all remaining attached to the compacted diamond carrier material.

After growth is complete, the grown CVD diamond may be more easily processed if it remains attached the compacted diamond carrier material, as the compacted diamond carrier material provides a rigid mechanical support. For example, it could remain attached to the grown CVD diamond while laser is carried out, and then subsequently removed.

A further benefit provided by grown using a hot compacted diamond carrier material is that recessed growth techniques can be used. As described above, single crystal CVD diamond can be grown in a recess, and this allows the production of very thick (up to, say, 10 mm) single crystal CVD diamonds. Growing in a recess using a compacted diamond carrier material allows for good heat transfer both below and at the sides of the growing CVD diamond into the compacted diamond carrier material. Existing recessed growth techniques require expensive machining of hard metal carriers, whereas compacted diamond carrier material is very quick and inexpensive to machine. Furthermore, the ability to stop and start the process (unlike when using a hard metal recessed carrier) allows for the growth to be stopped. The growing single crystal CVD diamond stones can then be processed in some way (for example, by treating with a laser or polishing) and then the compacted diamond carrier material and single crystal CVD diamond stones can be returned to the reactor and the growth restarted.

An important property of the carrier substrate is how easily it can be removed from the grown diamond. Polycrystalline diamond (PCD) compacts, formed by HPHT sintering in a catalyst such as cobalt, form inter-grown diamond grains. This type of material is very difficult to machine away. In contrast, while the compacted diamond carrier has adequate handling strength, it does not have inter-grown diamond grains and is accordingly much easier to machine away from the grown CVD diamond. FIGS. 5 and 6 illustrate schematically inter-grown diamond grains formed by HPHT sintering of diamond in the presence of a catalyst (FIG. 6) and compacted diamond grains formed by HPHT sintering of diamond without any catalyst or sintering aid (FIG. 6). In FIG. 5, the diamond grains 6 are intergrown with one another such that each diamond grain interlocks with adjacent diamond grains, forming a very strong structure. Gaps between the diamond grains are filled with a catalyst material used during sintering, such as cobalt 7. The intergrowth of the diamond grains gives the PCD compact a high degree of abrasion resistance. In FIG. 6, the diamond grains 8 are not intergrown, but are bonded to one another over smaller areas and the material is therefore more friable; it is easier to remove diamond grains from the compact by machining. It is suggested that the bonding for the compacted diamond grains may be effected by bonding of non-diamond carbon.

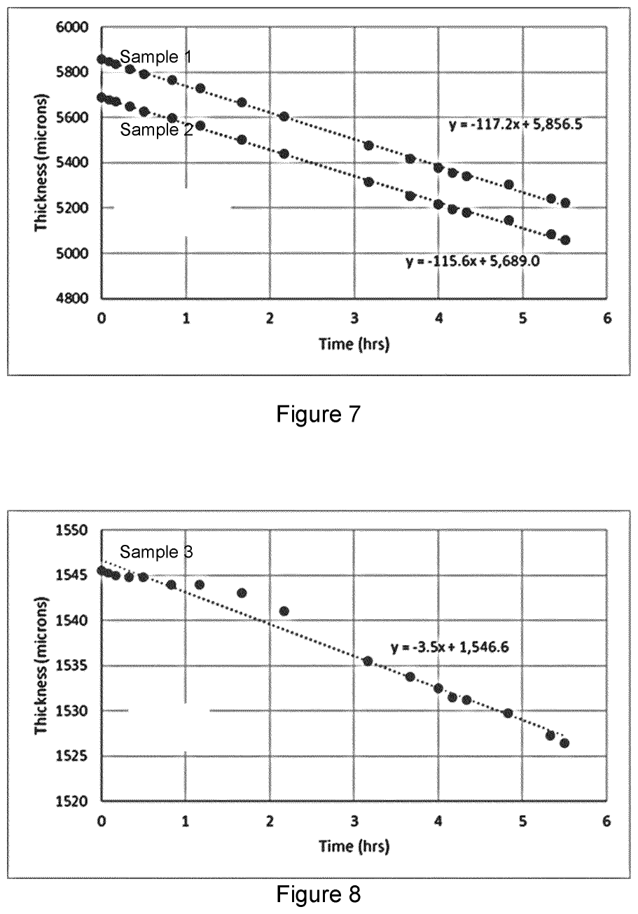

FIGS. 7 and 8 show the results of lapping testing performed on three materials; FIG. 7 shows the results of the lapping tests on samples 1 and 2, which were discs of compacted diamond carrier material with a weight of 190 g and an outer diameter of 50.85 mm. FIG. 8 shows the results of the lapping tests performed on sample 3, which was a disc of HPHT sintered polycrystalline diamond with intergrown grains. The three samples were each lapped five times using a Stahli™ lapper with a 20 inch non-slotted plate at 75 rpm using a mixture of 170 mesh diamond grit in Teclam™ carrier fluid. The concentration of the suspension was 160 g diamond grit per litre of carrier fluid. The mixture was added at a dose rate of 10 ml/minute.

The removal rate of material from the surface for sample 1 was 117 μm/hour. The removal rate of material from the surface for sample 2 was 116 μm/hour. The removal rate of material from the surface for sample 3 was 3 μm/hour. It can be seen that the compacted diamond carrier material is much easier to remove from the grown CVD diamond material. This is thought to be because the diamond grains in samples 1 and 2 are not intergrown, unlike the diamond grains of sample 3, and so can be more easily removed. Note that much higher removal rates have been achieved, depending on the density of the material and the specific conditions of lapping.

Another possible mechanism to remove the compacted diamond carrier material is to heat it in the presence of oxygen a temperature up to 700° C. It has been found, for example, that heating the composite of compacted diamond carrier material and overgrown CVD diamond in air at 650° C. for 4 hours causes the compacted diamond carrier material to revert to power, without affecting the CVD diamond. This powder can be simply brushed away. This is a particularly beneficial way of removing the compacted diamond carrier material if it is used as a non-planar carrier which would otherwise be difficult to process away by mechanical means. A further advantage of using compacted diamond carrier material on which to grow non-planar CVD diamond shapes is that non-planar carriers cannot flex and bow as easily as a planar carrier. Where there is a mismatch in thermal expansion coefficients between the growing diamond and the carrier, this lack of flexing can make it easy for the diamond to delaminate from the carrier material during growth, ruining the process. The use of a compacted diamond carrier material means that no delamination occurs.

It is observed that the compacted diamond carrier material does not revert to power if the heating is carried out in an oxygen free atmosphere. While the inventors do not wish to be limited by this theory, it is suggested that the diamond grains in the compacted diamond carrier material are bonded together via non-diamond carbon at the surface of the grains. Heating in the presence of oxygen causes etching of this non-diamond carbon, which mechanically weakens the structure and causes the compacted diamond carrier material to revert to powder.

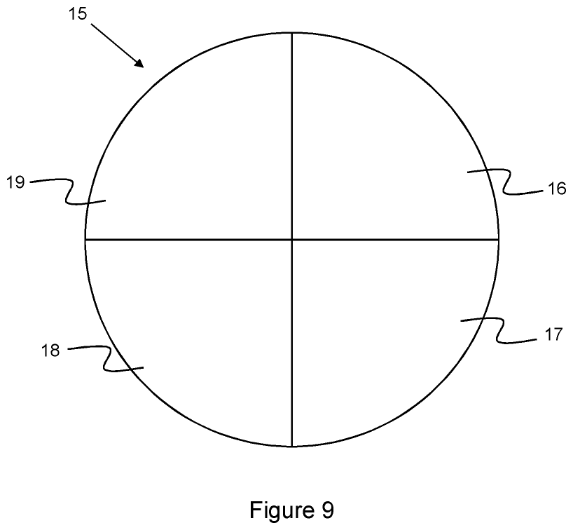

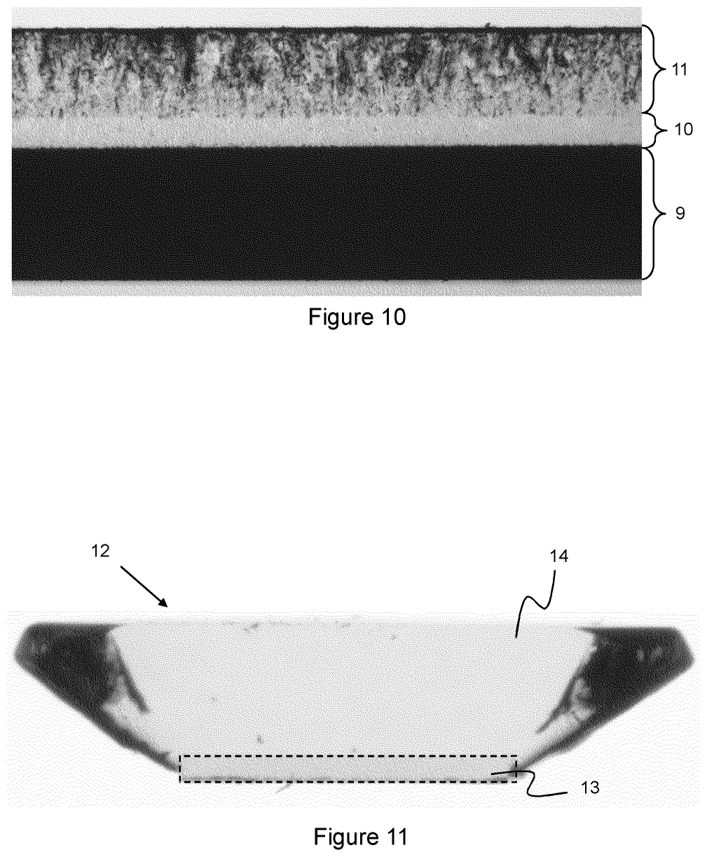

As described above, compacted diamond carrier material is typically formed at temperatures of 750° C. to 2000° C. and in a pressure range of 3 GPa to 8 GPa. This requires an HPHT press, which may have a limited volume capacity for pressing the compacted diamond carrier material. It may be required to produce a larger compacted diamond carrier than is available from an individual HPHT press. However, it is no problem to form a large compacted diamond carrier from segments of smaller blocks of compacted diamond carrier compacted diamond carrier material, as shown in FIG. 9. In this case, a compacted diamond carrier 15 is manufactured by joining four smaller blocks of compacted diamond carrier material 16, 17, 18, 19. Joining of these blocks 16, 17, 18, 19 may be done by any suitable means known to the skilled person. For example, they may be joined by brazing, mechanical keying (e.g. dovetailing to form an interference fit), or simply by wrapping a band around the periphery of the compacted diamond carrier 16. Provided there is still an adequate connection to allow even heat transfer, any joining technique may be used. Note that in the example of FIG. 9, the compacted diamond carrier 16 is shown as being circular in plan view but the skilled person will appreciate that any suitable shape may be used depending on the shape of grown diamond that is required and any constraints of the reactor in which growth is to occur.

In some circumstances, it may be desirable to coat the compacted diamond carrier material before attaching a single crystal diamond seed or before growing polycrystalline CVD diamond on the surface of the compacted diamond carrier material. For example, coating the compacted diamond carrier material with a very thin layer of a carbide forming material, such as silicon, can prevent any contamination from the compacted diamond carrier material from entering the growing diamond. If the layer is thin enough it will have a negligible effect on any thermal expansion coefficient mismatch.

### Example 1

In order to illustrate the invention, polycrystalline diamond was grown on a polycrystalline diamond carrier substrate consisting of compacted non-intergrown diamond particles substantially free of a second phase. Crushed diamond grits with an average particle size of 22 μm were compacted into a disc with a thickness of 5 mm and a diameter of 57 mm. To form a compact, the diamond grit was sintered at 1600° C. and 5 GPa for a dwell time of 20 minute. The resultant carrier substrate had a bulk density of 3.15 g/cm³, compared to the theoretical density of 3.514 g/cm³ for diamond. The carrier substrate was lapped and polished to give an Rₐ of no more than 1 μm.

The carrier substrate was acid-cleaned in H₂SO₄ and KNO₃ and seeded by brushing a surface with 0.1 μm diamond powder.

The carrier substrate was placed in a CVD reactor. A first layer of polycrystalline CVD diamond was grown in an atmosphere of methane, hydrogen, argon and nitrogen to a thickness of 0.30 mm. The growth was then stopped, the sample allowed to cool to room temperature, and then re-started at a higher power and with a higher methane content to increase growth rate. This resulted in the growth of a second layer of polycrystalline CVD diamond.

FIG. 9 is a photograph of a polished cross section through Example 1. The first layer 10 of polycrystalline CVD diamond had a thickness of 0.30 mm, and the second layer 11 of polycrystalline CVD diamond had a thickness of 0.76 mm. The total thickness of the carrier substrate 9, the first layer 10 and the second layer 11 was 2.23 mm.

It can be seen that there is no delamination between the carrier substrate 9 and the first layer 10 of polycrystalline CVD diamond, and no delamination between the first layer 10 of polycrystalline CVD diamond and the second layer 11 of polycrystalline CVD diamond despite the growth being restarted. This is because the thermal expansion coefficient of the carrier substrate 9 and the diamond layers 10, 11 is substantially the same and so no shear stresses develop at the interfaces between the carrier substrate 9 and the diamond layers 10, 11 on cooling or heating up.

### Example 2

A test was performed to assess the effect of restarting on single crystal CVD diamond material when grown on a compacted diamond carrier. Crushed diamond grits with an average particle size of 22 μm were compacted into a disc with a thickness of 5.05 mm and a diameter of 50.5 mm. To form a compact, the diamond grit was sintered at 1600° C. and 5 GPa for a dwell time of 20 minute. The resultant carrier substrate had a bulk density of 3.4955 g/cm³, compared to the theoretical density of 3.514 g/cm³ for diamond. The surface of the compacted diamond carrier was polished to an Rₐ surface roughness of no more than 1 μm.

Single crystal diamond seeds with nominal dimensions of 3.8×3.8×0.3 mm were attached to the surface of the compacted diamond carrier by brazing. The compacted diamond carrier was then loaded into a microwave CVD reactor and temperature and pressure suitable for growing single crystal CVD diamond were applied, along with source gases containing hydrogen and methane.

Growth was stopped and subsequently restarted a total of seven times. Each time growth was stopped, the compacted diamond carrier was allowed to cool to room temperature. The times of each growth run are provided in Table 1 below:

TABLE 1
Times of growth runs to grow a single crystal CVD diamond

| Restart number | Time/hours |
|---|---|
| 0 | 12.75 |
| 1 | 17.1 |
| 2 | 72 |
| 3 | 9 |
| 4 | 9 |
| 5 | 9 |
| 6 | 9 |
| 7 | 9 |

The resultant stone was removed from the compacted diamond carrier by heating the stone and carrier in air at 650° C. The stone was then sectioned and polished. A photograph showing a side elevation view of the sectioned CVD single crystal diamond stone 12 grown on the hot compacted diamond carrier is shown in FIG. 11.

The stone 12 showed no observable crystallographic twins. The original seed 13 was visible to the eye (highlighted with a dotted line in FIG. 11), but the grown CVD single crystal diamond 14 appeared to be homogeneous to the eye.

When observed under ultra-violet light, a small change in luminescence can be seen at the points where restarts occurred, but this was not evident to the eye even at high magnifications.

A further problem with the hot compacted diamond carrier is that the thermal conductivity is significantly lower than that of single crystal or fully sintered diamond. In some applications, for example growing CVD diamond on a compacted diamond carrier using high power density, a high thermal conductivity would be desirable in order to reduce temperature gradients which could result in shape change which makes delamination more likely. It is also desirable to reduce the amount of waste when using a hot compacted diamond carrier, as the hot compacted diamond carrier is a single-use carrier when used as a carrier for growing CVD synthetic diamond, and each carrier can require over 100-ct of diamond powder to manufacture.

As noted above, fully leached PCD diamond and CVD diamond have a much higher thermal conductivity TC than or hot compacted diamond. The inventors have therefore developed a system in which a plate of leached PCD diamond or polycrystalline CVD diamond is placed in a HPHT press with a covering of diamond power. During hot compaction, a thin layer of hot compacted diamond is be formed on a surface of the PCD or polycrystalline CVD diamond.

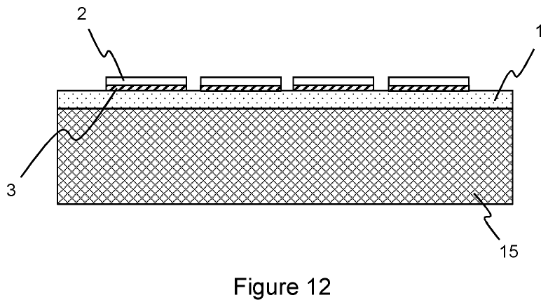

An exemplary carrier is illustrated in FIG. 12, which is similar to FIG. 3 except that the carrier substrate is a composite structure comprising a layer of compacted diamond carrier material 1 on a surface of a diamond material with a higher thermal conductivity 15, such as fully leached PCD diamond or CVD polycrystalline diamond, which may be backed by a carrier or unbacked. This composite structure, comprising a layer of high thermal conductivity diamond 15 and a layer of compacted diamond carrier material 1, is used as a carrier for CVD diamond growth. To recover any CVD diamond grown on the carrier, the hot compacted layer material 1 can be heated decompose when heated in air, or mechanically processed away, allowing any CVD diamond grown on top to be released. The high quality diamond layer 15 can be re-used, repeating the cycle. This provides a high thermal conductivity carrier, and limits the amount of waste of diamond powder.

While this invention has been particularly shown and described with reference to preferred embodiments, it will be understood to those skilled in the art that various changes in form and detail may be made without departing from the scope of the invention as defined by the appendant claims.

1. A method of fabricating a CVD synthetic diamond material, the method comprising:
providing a compacted diamond carrier material consisting of compacted non-intergrown diamond particles substantially free of a second phase;
growing CVD synthetic diamond material on a surface of the compacted diamond carrier material.

2. The method according to claim 1, further comprising separating the grown CVD synthetic diamond material from the compacted diamond carrier material.

3. The method according to claim 1, wherein the compacted diamond carrier material has a density of between 80.0 and 99.5% of the theoretical density of diamond.

4-7. (canceled)

8. The method according to claim 1, further comprising:
attaching at least one single crystal diamond seed to the compacted diamond carrier material;
wherein the grown CVD synthetic diamond material comprises a single crystal CVD diamond grown on the single crystal diamond seed;
the method further comprising separating the grown single crystal CVD diamond from the compacted diamond carrier material and any polycrystalline CVD diamond material which has grown to yield a grown single crystal CVD diamond.

9. The method according to claim 8, wherein the single crystal diamond seed is attached to the compacted diamond carrier material by a method selected from any of:
soldering to a surface of the compacted diamond carrier material;
brazing to a surface of the compacted diamond carrier material;
embedding the single crystal diamond seed into the surface of the compacted diamond carrier material;
locating the single crystal diamond seed in a recess in the surface of compacted diamond carrier material.

10-11. (canceled)

12. The method according to claim 1, further comprising, after growing CVD synthetic diamond material on the compacted diamond carrier material, stopping the growth process and subsequently growing further CVD synthetic diamond material on the grown CVD synthetic diamond material.

13. The method according to claim 1, further comprising providing the compacted diamond carrier material by compacting diamond grit at a temperature between 750° C. and 2000° C. and a pressure of between 3 and 8 GPa.

14-16. (canceled)

17. A composite diamond body comprising:
a first layer of compacted diamond carrier material consisting of compacted non-intergrown diamond particles substantially free of a second phase;
at least one single crystal diamond material wafer affixed to a surface of the layer of compacted non-intergrown diamond particles.

18. A composite diamond body comprising:
a first layer of compacted diamond carrier material consisting of compacted non-intergrown diamond particles substantially free of a second phase;
a layer of CVD synthetic polycrystalline diamond material grown on a surface of the first layer.

19. A composite diamond body comprising:
a first layer of compacted diamond carrier material consisting of compacted non-intergrown diamond particles substantially free of a second phase;
a second layer of synthetic diamond material to which the first layer is attached, the second layer having a higher thermal conductivity than the first layer.

20-23. (canceled)

24. The composite diamond body according to claim 18, wherein the layer of CVD synthetic polycrystalline diamond material has a thickness in a range of 1 to 10 mm.
